(19) United States
(12) Patent Application Publication
(10) Pub. No.: US 2012/0132948 A1
(43) Pub. Date: May 31, 2012

(54) SEMICONDUCTOR LIGHT EMITTING DEVICE AND METHOD FOR MANUFACTURING THE SAME

(75) Inventors: Shinji Nunotani, Tokyo (JP); Masaaki Ogawa, Kanagawa-ken (JP); Koji Asakawa, Kanagawa-ken (JP); Ryota Kitagawa, Tokyo (JP); Akira Fujimoto, Kanagawa-ken (JP); Takanobu Kamakura, Kanagawa-ken (JP)

(73) Assignee: KABUSHIKI KAISHA TOSHIBA, Tokyo (JP)

(21) Appl. No.: 13/229,972

(22) Filed: Sep. 12, 2011

(30) Foreign Application Priority Data
Nov. 26, 2010 (JP) 2010-263449

(51) Int. Cl. H01L 33/36

(52) U.S. Cl. 257/99; 438/22; 257/E33.062

(57) ABSTRACT

According to one embodiment, a semiconductor light emitting device includes a light emitter, a first and a second electrode layer, a pad electrode and an auxiliary electrode portion. The emitter includes a first semiconductor layer provided on one side of the emitter, a second semiconductor layer provided on one other side of the emitter, and a light emitting layer provided between the first and second semiconductor layers. The first electrode layer is provided on opposite side of the second semiconductor layer from the first semiconductor layer and includes a metal layer and a plurality of apertures penetrating through the metal layer. The second electrode layer is electrically continuous with the first semiconductor layer. The pad electrode is electrically continuous with the first electrode layer. The auxiliary electrode portion is electrically continuous with the first electrode layer and extends in a second direction orthogonal to the first direction.

### CROSS-REFERENCE TO RELATED APPLICATIONS

This application is based upon and claims the benefit of priority from the prior Japanese Patent Application No. 2010-263449, filed on Nov. 26, 2010; the entire contents of which are incorporated herein by reference.

### FIELD

Embodiments described herein relate generally to a semiconductor light emitting device and a method for manufacturing the same.

### BACKGROUND

A semiconductor light emitting device includes an electrode in ohmic contact with the surface of a semiconductor layer. The semiconductor light emitting device is caused to emit light by passing a current through this electrode. Here, in illumination apparatuses, for instance, a relatively large light emitting device is desired. To this end, in a semiconductor light emitting device, a metal electrode can be provided entirely on the light emitting surface, and ultrafine apertures on the nanometer (nm) scale can be formed in the metal electrode. However, in a semiconductor light emitting device, the light emission intensity at the light emitting surface needs to be made more uniform.

### BRIEF DESCRIPTION OF THE DRAWINGS

FIG. 1 is a schematic perspective view illustrating the configuration of a light emitting device according to a first embodiment;

FIGS. 2A and 2B are schematic views of the light emitting device according to the first embodiment;

FIGS. 3A to 3C are schematic plan views illustrating the light emission distribution;

FIGS. 4A to 4G are schematic views describing other examples of the auxiliary electrode portion;

FIGS. 5A and 5B are schematic views illustrating a semiconductor light emitting device according to a second embodiment;

FIGS. 6A and 6B are schematic views illustrating a semiconductor light emitting device according to a third embodiment;

FIGS. 7A and 7B are schematic views illustrating a semiconductor light emitting device according to a fourth embodiment;

FIG. 8A to FIG. 11C are schematic sectional views describing examples of a method for manufacturing a semiconductor light emitting device; and

FIG. 12 is a schematic sectional view illustrating an alternative semiconductor light emitting device.

### DETAILED DESCRIPTION

In general, according to one embodiment, a semiconductor light emitting device includes a light emitter, a first electrode layer, a second electrode layer, a pad electrode and an auxiliary electrode portion. The light emitter includes a first semiconductor layer of a first conductivity type provided on one side of the light emitter, a second semiconductor layer of a second conductivity type provided on one other side of the light emitter, and a light emitting layer provided between the first semiconductor layer and the second semiconductor layer. The first electrode layer is provided on opposite side of the second semiconductor layer from the first semiconductor layer and includes a metal layer and a plurality of apertures penetrating through the metal layer along a first direction directed from the first semiconductor layer toward the second semiconductor layer. The second electrode layer is electrically continuous with the first semiconductor layer. The pad electrode is electrically continuous with the first electrode layer. The auxiliary electrode portion is electrically continuous with the first electrode layer and extends in a second direction orthogonal to the first direction.

In general, according to one other embodiment, a method is disclosed for manufacturing a semiconductor light emitting device. The method can include forming a light emitter. The light emitter includes a first semiconductor layer of a first conductivity type provided on one side of the light emitter, a second semiconductor layer of a second conductivity type provided on one other side of the light emitter, and a light emitting layer provided between the first semiconductor layer and the second semiconductor layer. The method can include forming a metal layer on the second semiconductor layer. The method can include forming a mask pattern on the metal layer and etching the metal layer through the mask pattern to form an electrode layer including a plurality of apertures penetrating through the metal layer along a first direction directed from the first semiconductor layer toward the second semiconductor layer. In addition, the method can include forming an auxiliary electrode portion. The auxiliary electrode portion is electrically continuous with the electrode layer and extends in a second direction orthogonal to the first direction.

In general, according to one other embodiment, a method is disclosed for manufacturing a semiconductor light emitting device. The method can include forming a light emitter. The light emitter includes a first semiconductor layer of a first conductivity type provided on one side of the light emitter, a second semiconductor layer of a second conductivity type provided on one other side of the light emitter, and a light emitting layer provided between the first semiconductor layer and the second semiconductor layer. The method can include forming an auxiliary electrode portion on the second semiconductor layer. The auxiliary electrode portion extends in a second direction orthogonal to a first direction directed from the first semiconductor layer toward the second semiconductor layer. The method can include forming a metal layer on the second semiconductor layer and the auxiliary electrode portion. In addition, the method can include forming a mask pattern on the metal layer and etching the metal layer through the mask pattern to form an electrode layer including a plurality of apertures penetrating through the metal layer along the first direction.

In general, according to one other embodiment, a method is disclosed for manufacturing a semiconductor light emitting device. The method can include forming a light emitter. The light emitter includes a first semiconductor layer of a first conductivity type provided on one side of the light emitter, a second semiconductor layer of a second conductivity type provided on one other side of the light emitter, and a light emitting layer provided between the first semiconductor layer and the second semiconductor layer. The method can include forming a metal layer on the second semiconductor layer. In addition, the method can include forming a mask pattern on the metal layer and etching the metal layer through the mask pattern to form an electrode layer including a plurality of apertures penetrating through the metal layer along a first direction directed from the first semiconductor layer toward the second semiconductor layer. The electrode layer further includes an auxiliary electrode portion extending in a second direction orthogonal to the first direction.

Various embodiments will be described hereinafter with reference to the accompanying drawings.

The drawings are schematic or conceptual. The relationship between the thickness and the width of each portion, and the size ratio between the portions, for instance, are not necessarily identical to those in reality. Furthermore, the same portion may be shown with different dimensions or ratios depending on the figures.

In the present specification and the drawings, components similar to those described previously with reference to earlier figures are labeled with like reference numerals, and the detailed description thereof is omitted as appropriate.

In the following description, by way of example, it is assumed that the first conductivity type is n-type and the second conductivity type is p-type.

### First Embodiment

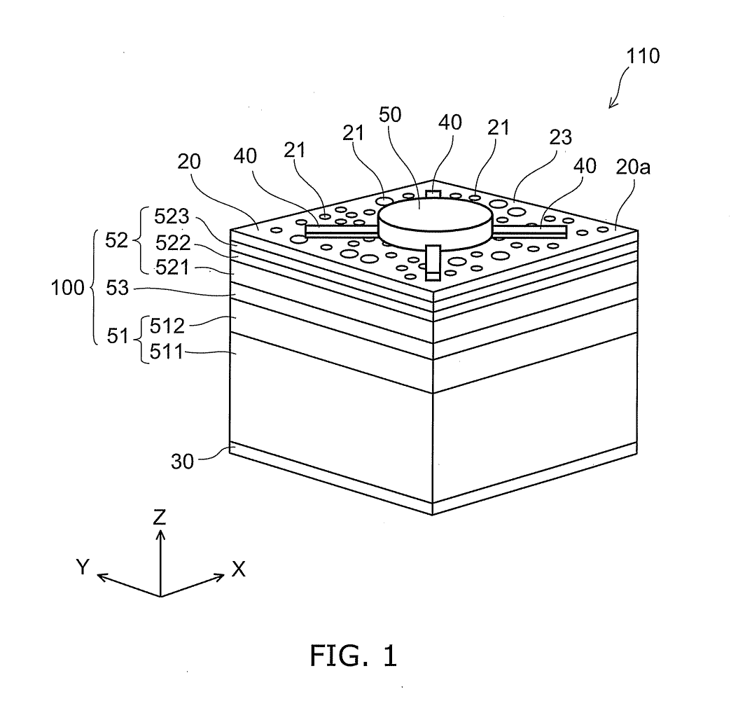

FIG. 1 is a schematic perspective view illustrating the configuration of a semiconductor light emitting device according to a first embodiment.

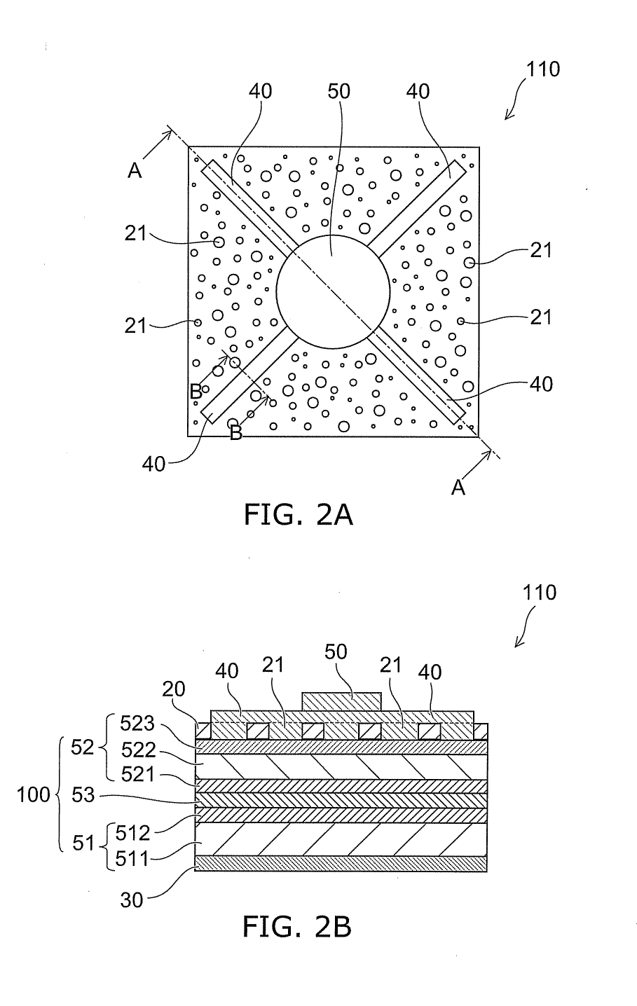

FIG. 2A is a schematic plan view of the semiconductor light emitting device according to the first embodiment.

FIG. 2B is a schematic sectional view in the direction of arrow A-A shown in FIG. 2A.

The semiconductor light emitting device 110 according to the first embodiment includes a light emitter 100, a first electrode layer 20, a second electrode layer 30, and an auxiliary electrode portion 40.

The light emitter 100 includes a first semiconductor layer 51 of the first conductivity type, a second semiconductor layer 52 of the second conductivity type, and a light emitting layer 53 provided between the first semiconductor layer 51 and the second semiconductor layer 52.

The first semiconductor layer 51 includes a cladding layer 512 made of e.g. n-type InAlP. The cladding layer 512 is formed on a substrate 511 made of e.g. n-type GaAs. In the embodiment, for convenience, it is assumed that the substrate 511 is included in the first semiconductor layer 51.

The second semiconductor layer 52 includes a cladding layer 521 made of e.g. p-type InAlP. On the cladding layer 521, a current spreading layer 522 made of e.g. p-type InGaAlP is provided. A contact layer 523 is provided thereon. In the embodiment, for convenience, it is assumed that the current spreading layer 522 and the contact layer 523 are included in the second semiconductor layer 52.

The light emitting layer 53 is provided between the first semiconductor layer 51 and the second semiconductor layer 52. In the semiconductor light emitting device 110, for instance, the cladding layer 512 of the first semiconductor layer 51, the light emitting layer 53, and the cladding layer 521 of the second semiconductor layer 52 constitute a heterostructure.

The light emitting layer 53 may have e.g. an MQW (multiple quantum well) structure in which barrier layers and well layers are alternately repeated. Alternatively, the light emitting layer 53 may include an SQW (single quantum well) structure in which a well layer is sandwiched by a pair of barrier layers.

The first electrode layer 20 is provided on the opposite side of the second semiconductor layer 52 from the first semiconductor layer 51.

In the embodiment, for convenience of description, the second semiconductor layer 52 side of the light emitter 100 is referred to as the front surface side or upper side, and the first semiconductor layer 51 side of the light emitter 100 is referred to as the rear surface side or lower side. Furthermore, the first direction from the first semiconductor layer 51 toward the second semiconductor layer 52 is referred to as Z direction, and the second directions orthogonal to the first direction are referred to as X direction and Y direction.

The first electrode layer 20 includes a metal portion 23 and a plurality of apertures 21 penetrating through the metal portion 23 along the Z direction. Each of the plurality of apertures 21 has a circle equivalent diameter of e.g. 10 nm or more and 5 μm or less.

Here, the circle equivalent diameter is defined by the following equation:

Circle equivalent diameter=2×(area/n)^{1/2}

where “area” is the area of the aperture as viewed in the Z direction.

If the circle equivalent diameter of the aperture 21 exceeds 5 μm, a region without current flow occurs. This interferes with decreasing of series resistance and decreasing of forward voltage. Furthermore, it is desired that the effect of light transmittance (transmittance for externally transmitting light generated in the light emitting layer 53) in the first electrode layer 20 surpass the effect of aperture ratio (the ratio of the area of the aperture to the area of the first electrode layer 20). To this end, preferably, the circle equivalent diameter is approximately ½ or less of the center wavelength of light generated in the light emitting layer 53. For instance, for visible light, the circle equivalent diameter of the aperture 21 is preferably 300 nm or less.

On the other hand, the lower limit of the circle equivalent diameter of the aperture 21 is not restricted from the viewpoint of resistance. However, in terms of manufacturability, the circle equivalent diameter is preferably 10 nm or more, and more preferably 30 nm or more.

The aperture 21 does not necessarily need to be circular. Hence, in the embodiment, the above definition of the circle equivalent diameter is used to specify the aperture 21.

The metal used for the material of the first electrode layer 20 is not limited as long as it has sufficient electrical and thermal conductivity. The first electrode layer 20 can be made of any metal generally used for electrodes. Here, from the viewpoint of absorption loss, Ag or Au is preferably used as the base metal. Furthermore, to ensure adhesiveness and heat resistance, at least one material selected from Al, Zn, Zr, Si, Ge, Pt, Rh, Ni, Pd, Cu, Sn, C, Mg, Cr, Te, Se, and Ti, or an alloy thereof may be used. The second metal layer 30 may be provided as a multilayer structure including the above material.

Any two points in the metal portion 23 (the portion where the apertures 21 are not provided) of the first electrode layer 20 are seamlessly continuous with each other, and with at least a current supply source such as a pad electrode. The reason for this is to ensure electrical continuity to keep the resistance low.

From the viewpoint of the resistance of the first electrode layer 20, the sheet resistance of the first electrode layer 20 is preferably 10Ω/□ or less, and more preferably 5Ω/□. As the sheet resistance becomes lower, heat generation of the semiconductor light emitting device 110 decreases. Furthermore, light emission is made more uniform, and the brightness increases more significantly.

From the viewpoint of the sheet resistance described above, the thickness of the first electrode layer 20 is 10 nm or more. On the other hand, as the thickness of the first electrode layer 20 becomes thicker, the resistance decreases. To ensure the transmittance for light generated in the light emitting layer 53, the upper limit of the thickness of the first electrode layer 20 is preferably 50 nm or less.

Here, the first electrode layer 20 has a bulk reflectance of 70% or more. This allows the light generated in the light emitting layer 53 to pass through the first electrode layer 20.

In addition, an intermediate layer, not shown, may be provided between the first electrode layer 20 and the second semiconductor layer 52. The intermediate layer is made of e.g. a metal oxide film. If the intermediate layer is provided, the second semiconductor layer 52 and the first electrode layer 20 are not in direct contact with each other. Hence, no light absorption layer is formed, which otherwise occurs at the contact interface of the second semiconductor layer 52 when the second semiconductor layer 52 and the first electrode layer 20 are in direct contact with each other. Hence, the external emission efficiency of light generated in the light emitting layer 53 can be increased.

The second electrode layer 30 is electrically continuous with the first semiconductor layer 51. In this example, the second electrode layer 30 is provided on the rear surface side of the light emitter 100. The second electrode layer 30 is made of e.g. Au. The second electrode layer 30 may be made of at least one material selected from Au, Ag, Al, Zn, Zr, Si, Ge, Pt, Rh, Ni, Pd, Cu, Sn, C, Mg, Cr, Te, Se, Ti, O, H, W, and Mo or an alloy thereof. The second electrode layer 30 may be provided as a multilayer structure including the above material.

The auxiliary electrode portion 40 is electrically continuous with the first electrode layer 20 and extends in the direction orthogonal to the Z direction (in the direction along the XY plane). In the semiconductor light emitting device 110 illustrated in FIG. 1, a pad electrode 50 having a generally circular shape is provided generally at the center of the first electrode layer 20. The auxiliary electrode portion 40 extends radially from the pad electrode 50. The semiconductor light emitting device 110 includes four auxiliary electrode portions 40.

The auxiliary electrode portions 40 extend toward the respective corners of the first electrode layer 20 shaped like a rectangle as viewed in the Z direction.

The auxiliary electrode portion 40 does not necessarily need to be in contact with the pad electrode 50. This is because the current supplied from the pad electrode 50 flows to the auxiliary electrode portion 40 through the first electrode layer 20.

The auxiliary electrode portion 40 is made of at least one material selected from Au, Ag, Al, Zn, Zr, Si, Ge, Pt, Rh, Ni, Pd, Cu, Sn, C, Mg, Cr, Te, Se, Ti, O, H, W, and Mo or an alloy thereof.

As shown in FIGS. 2A and 2B, the auxiliary electrode portion 40 is formed on the first electrode layer 20 including a plurality of apertures 21. That is, the auxiliary electrode portion 40 is provided on the opposite side of the first electrode layer 20 from the second semiconductor layer 52. In the aperture 21 on which the auxiliary electrode portion 40 is provided, the metal of the material of the auxiliary electrode portion 40 may be buried.

The thickness along the Z direction of the auxiliary electrode portion 40 is e.g. 10 nm or more and less than 5 μm. The width along the direction orthogonal to the extending direction of the auxiliary electrode portion 40 is e.g. 1 μm or more and less than 50 μm.

In such a semiconductor light emitting device 110, the surface with the first electrode layer 20 formed thereon is used as a main light emitting surface. That is, in response to application of a prescribed voltage between the first electrode layer 20 and the second electrode layer 30, light having a prescribed center wavelength is emitted from the light emitting layer 53. This light is emitted outside primarily from the major surface 20a of the first electrode layer 20.

In the semiconductor light emitting device 110, when a current is externally supplied to the first electrode layer 20, the current can be sufficiently fed throughout the major surface 20a through the auxiliary electrode portion 40. Thus, light can be uniformly emitted throughout the major surface 20a.

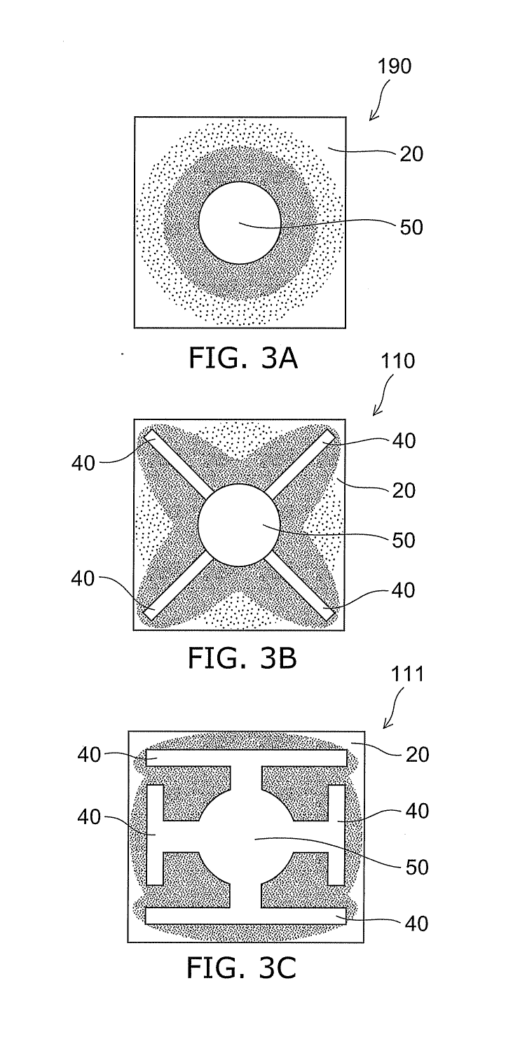

FIGS. 3A to 3C are schematic plan views illustrating the light emission distribution.

More specifically, FIGS. 3A to 3C schematically show the light emission distribution at the light emitting surface of the semiconductor light emitting device. FIG. 3A illustrates the case of a semiconductor light emitting device 190 including only a circular pad electrode. FIG. 3B illustrates the case of the semiconductor light emitting device 110 including a circular pad electrode 50 and auxiliary electrode portions 40 extending toward the corners. FIG. 3C illustrates the case of a semiconductor light emitting device 111 including a circular pad electrode 50 and auxiliary electrode portions 40 extending along the edge of the outline of the first electrode layer 20.

In any of the semiconductor light emitting devices 190, 110, and 111, the first electrode layer 20 includes a plurality of apertures 21. Furthermore, the semiconductor light emitting devices 190, 110, and 111 are supplied with a current from the pad electrode 50.

Light emission is performed in the entire surface of the first electrode layer 20. The portion with relatively high light emission intensity is indicated by dots. In the dotted portion, the portion with particularly high light emission intensity is indicated by dark dots.

In the semiconductor light emitting device 190 shown in FIG. 3A, light emission intensely occurs around the pad electrode 50, and is weakened toward the periphery.

In the semiconductor light emitting device 110 shown in FIG. 3B, light emission intensely occurs not only around the pad electrode 50 but also around the auxiliary electrode portion 40. That is, the region of intense light emission is larger than in the semiconductor light emitting device 190 shown in FIG. 3A.

In the semiconductor light emitting device 111 shown in FIG. 3C, the region of intense light emission is even larger than in the semiconductor light emitting device 110 shown in FIG. 3B.

Here, the pad electrode 50 and the auxiliary electrode portion 40 are not transmissive to light. Hence, the shape and size of the pad electrode 50 and the auxiliary electrode portion 40 are configured by the overall balance of light emission intensity and light emission distribution.

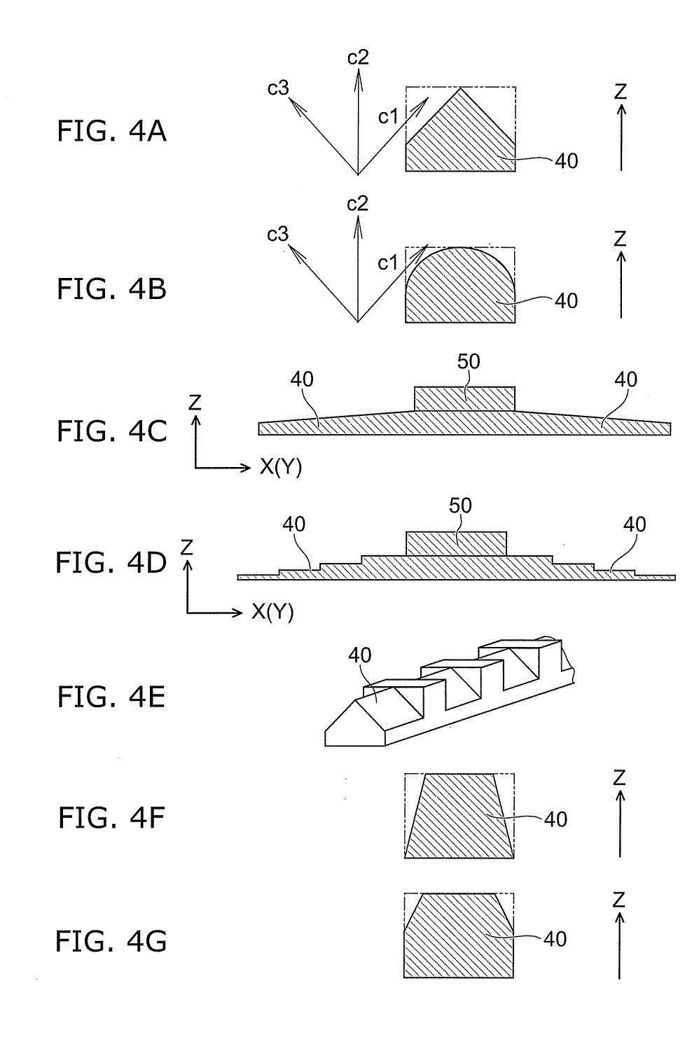

FIGS. 4A to 4G are schematic views describing other examples of the auxiliary electrode portion.

For the purpose of description, FIGS. 4A to 4G show schematic sectional views or schematic perspective views of only the auxiliary electrode portion. FIGS. 4A and 4B are sectional views in the direction of arrow B-B shown in FIG. 2A. FIG. 4C is a sectional view in the direction of arrow A-A shown in FIG. 2A.

In the auxiliary electrode portion 40 illustrated in FIGS. 4A and 4B, the width along the direction orthogonal to the extending direction is narrowed with the distance from the second semiconductor layer 52 along the Z direction.

In the auxiliary electrode portion 40 illustrated in FIG. 4A, the cross section has a tapered shape. In the auxiliary electrode portion 40 illustrated in FIG. 4B, the cross section has a semicircular shape.

Such cross-sectional shapes of the auxiliary electrode portion 40 can suppress blocking of emitted light by the auxiliary electrode portion 40 as compared with the case where the cross section of the auxiliary electrode portion 40 is rectangular.

More specifically, arrows c1-c3 shown in FIGS. 4A and 4B indicate example traveling directions of emitted light. As indicated by the double-dot-dashed line in the figure, in the case where the cross section of the auxiliary electrode portion 40 is rectangular, the light of arrow c3 having a prescribed angle is blocked by the auxiliary electrode portion 40.

On the other hand, in the case where the cross section of the auxiliary electrode portion 40 has a tapered or semicircular shape, the light of arrow c3 is not blocked by the auxiliary electrode portion 40. Hence, the light emission efficiency can be increased.

In the auxiliary electrode portion 40 illustrated in FIG. 4C, the thickness along the Z direction of the auxiliary electrode portion 40 is gradually decreased along the extending direction. The light emission intensity is weakened toward the tip of the auxiliary electrode portion 40. On the other hand, as the thickness of the auxiliary electrode portion 40 becomes thinner, the emitted light is less likely to be blocked. Hence, if the thickness is made thinner toward the tip of the auxiliary electrode portion 40, blocking of light is suppressed, and the decrease of light emission intensity can be compensated.

In the auxiliary electrode portion 40 illustrated in FIG. 4D, the thickness along the Z direction of the auxiliary electrode portion 40 is decreased stepwise toward the tip. As an example of the thickness of the auxiliary electrode portion 40 gradually decreased along the extending direction, such stepwise change may be included.

In the auxiliary electrode portion 40 illustrated in FIG. 4E, the auxiliary electrode portion 40 partly includes a portion having a tapered cross-sectional shape. Here, the cross-sectional shape of part of the auxiliary electrode portion 40 may be semicircular as illustrated in FIG. 4B.

FIG. 4F is a sectional view in the direction of arrow B-B shown in FIG. 2A. As in this auxiliary electrode portion 40, the cross-sectional shape may be trapezoidal. FIG. 4G is a sectional view in the direction of arrow B-B shown in FIG. 2A. As in this auxiliary electrode portion 40, the cross-sectional shape may be rectangular on the lower side, and trapezoidal on the upper side.

As described above, any shape is applicable as long as the width along the direction orthogonal to the extending direction of the auxiliary electrode portion 40 is narrowed with the distance from the second semiconductor layer 52 along the Z direction.

### Second Embodiment

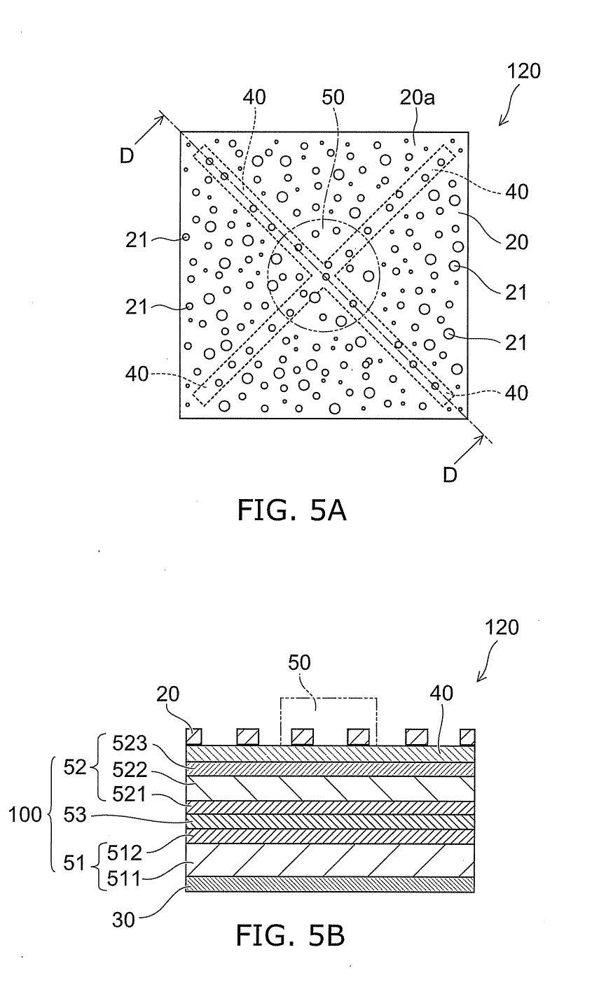

FIGS. 5A and 5B are schematic views illustrating a semiconductor light emitting device according to a second embodiment.

FIG. 5A is a schematic plan view illustrating the semiconductor light emitting device according to the second embodiment. FIG. 5B is a schematic sectional view in the direction of arrow D-D shown in FIG. 5A.

As shown in FIGS. 5A and 5B, in the semiconductor light emitting device 120 according to the second embodiment, the auxiliary electrode portion 40 is provided between the first electrode layer 20 and the second semiconductor layer 52.

The pad electrode 50 is provided as necessary on the first electrode layer 20. As shown in FIG. 5A, the auxiliary electrode portion 40 extends from the general center toward each corner of the first electrode layer 20.

Thus, the auxiliary electrode portion 40 is provided between the first electrode layer 20 and the second semiconductor layer 52. Also in this case, the current can be sufficiently fed throughout the major surface 20a through the auxiliary electrode portion 40. Thus, light can be uniformly emitted throughout the major surface 20a.

### Third Embodiment

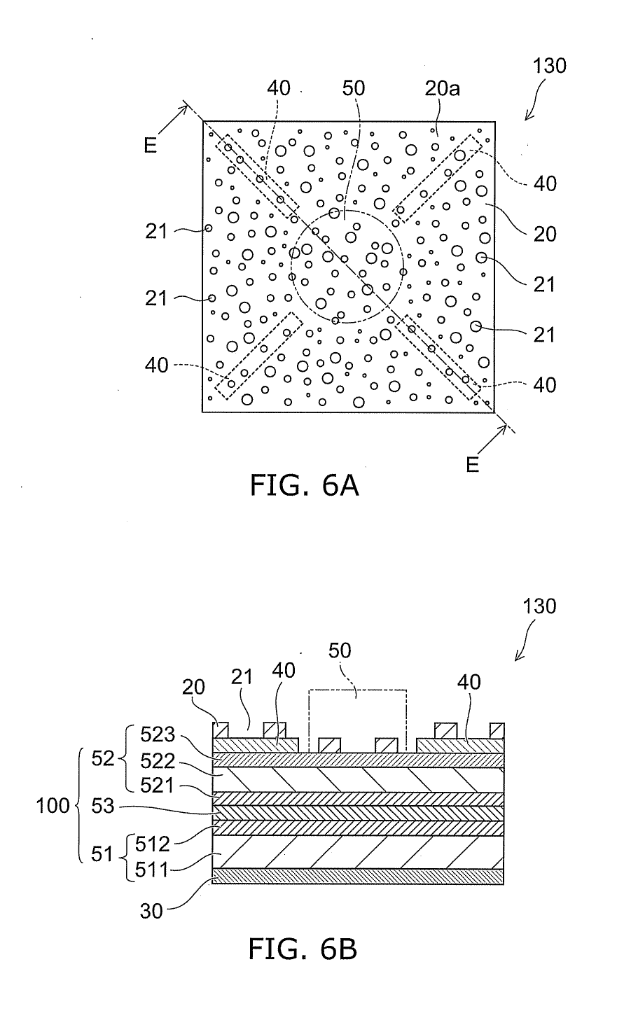

FIGS. 6A and 6B are schematic views illustrating a semiconductor light emitting device according to a third embodiment.

FIG. 6A is a schematic plan view illustrating the semiconductor light emitting device according to the third embodiment. FIG. 6B is a schematic sectional view in the direction of arrow E-E shown in FIG. 6A.

As shown in FIGS. 6A and 6B, in the semiconductor light emitting device 130 according to the third embodiment, the auxiliary electrode portion 40 is provided between the first electrode layer 20 and the second semiconductor layer 52.

The pad electrode 50 is provided as necessary on the first electrode layer 20. As shown in FIG. 6A, in the semiconductor light emitting device 130, four auxiliary electrode portions 40 are placed so as to extend from the general center toward the respective corners of the first electrode layer 20. The four auxiliary electrode portions 40 are spaced from each other. In the case where a pad electrode 50 is provided, the auxiliary electrode portion 40 and the pad electrode 50 are not in contact with each other.

Thus, the four auxiliary electrode portions 40 are spaced from each other. Also in this case, if a current is supplied from e.g. the pad electrode 50 to the first electrode layer 20, the current can be sufficiently fed throughout the major surface 20a through the auxiliary electrode portion 40 electrically continuous with the first electrode layer 20. Thus, light can be uniformly emitted throughout the major surface 20a.

### Fourth Embodiment

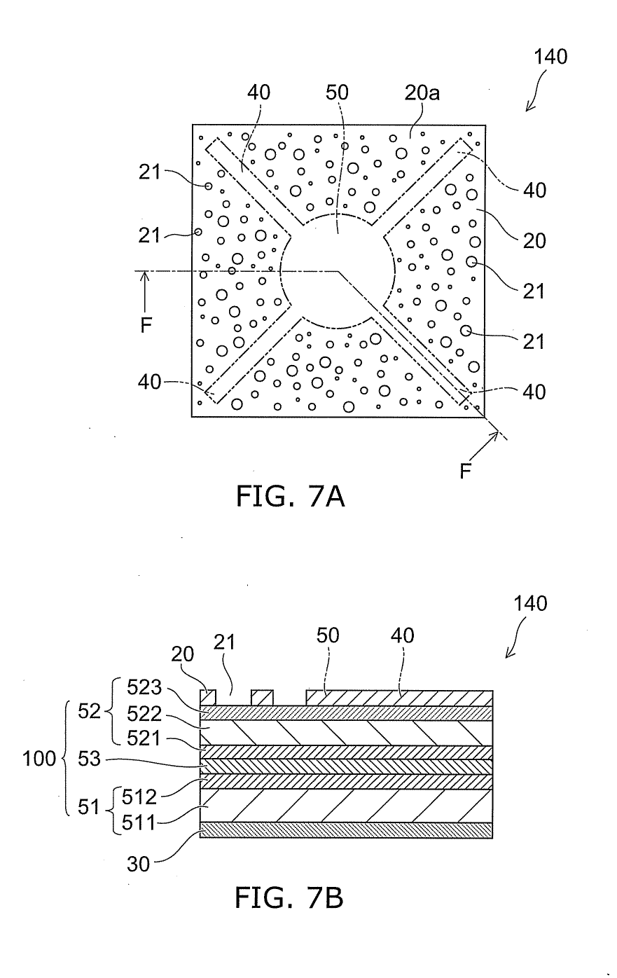

FIGS. 7A and 7B are schematic views illustrating a semiconductor light emitting device according to a fourth embodiment.

FIG. 7A is a schematic plan view illustrating the semiconductor light emitting device according to the fourth embodiment. FIG. 7B is a schematic sectional view in the direction of arrow F-F shown in FIG. 7A.

As shown in FIGS. 7A and 7B, in the semiconductor light emitting device 140 according to the fourth embodiment, the auxiliary electrode portion 40 is provided in the same layer as the first electrode layer 20.

In the semiconductor light emitting device 140, the region of the first electrode layer 20 including no aperture 21 constitutes the auxiliary electrode portion 40. Here, part of the region of the first electrode layer 20 including no aperture 21 may be used as necessary as a pad electrode 50.

Thus, the auxiliary electrode portion 40 is provided in the same layer as the first electrode layer 20. Also in this case, the current flowing into the first electrode layer 20 can be fed throughout the major surface 20a through the auxiliary electrode portion 40. Thus, light can be uniformly emitted throughout the major surface 20a.

Furthermore, in the semiconductor light emitting device 140, the auxiliary electrode portion 40 is provided integrally with the first electrode layer 20. Hence, the auxiliary electrode portion 40 can be formed in the same process as the first electrode layer 20. Thus, the manufacturing process can be simplified as compared with the case of forming the auxiliary electrode portion 40 in a process separate from that for the first electrode layer 20.

### Fifth Embodiment

The fifth embodiment is an example of a method for manufacturing the semiconductor light emitting device 110.

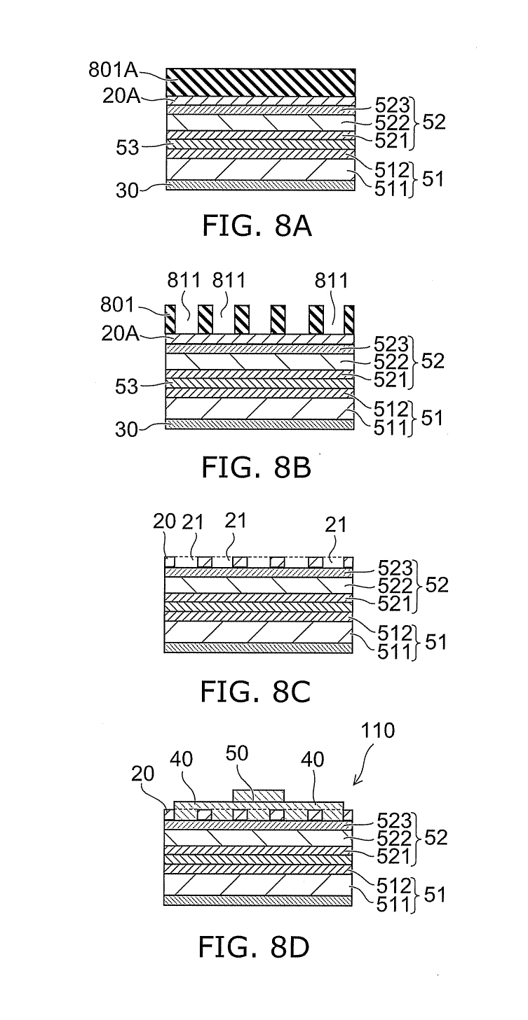

FIGS. 8A to 8D are schematic sectional views describing an example of the method for manufacturing the semiconductor light emitting device 110.

First, as shown in FIG. 8A, a light emitting layer 53 is formed on a first semiconductor layer 51, and a second semiconductor layer 52 is formed on the light emitting layer 53. Furthermore, a second electrode layer 30 is formed on the first semiconductor layer 51.

Next, a metal layer 20A is formed on the contact layer 523 of the second semiconductor layer 52. Then, a layer of resist 801A is formed on the metal layer 20A.

Next, the resist 801A is patterned to form a resist pattern 801 including resist apertures 811 as shown in FIG. 8B. The resist pattern 801 can be formed by various methods such as a method using self-assembly of block copolymer, a method using a stamper, a method using electron beam writing, and a method using a fine particle mask.

Next, the resist pattern 801 including the resist apertures 811 is used as a mask to perform ion milling to etch the metal layer 20A. Thus, apertures 21 are formed in the metal layer 20A corresponding to the resist apertures 811 (FIG. 8C). The metal layer 20A is turned into a first electrode layer 20 by the formation of the apertures 21. After the etching of the metal layer 20A, the resist pattern 801 is removed.

Next, as shown in FIG. 8D, an auxiliary electrode portion 40 is formed on the first electrode layer 20. To form the auxiliary electrode portion 40, resist is applied onto the first electrode layer 20, and an aperture of the resist is formed at the position for forming the auxiliary electrode portion 40. Through the resist with the aperture formed therein, the material of the auxiliary electrode portion 40 is evaporated. Subsequently, the resist is removed. Thus, the material formed in the aperture of the resist is left on the first electrode layer 20 and constitutes an auxiliary electrode portion 40.

Here, to form the auxiliary electrode portion 40 of the cross-sectional shape shown in FIGS. 4A and 4B, the cross section in the aperture of the resist for forming the auxiliary electrode portion 40 is shaped into an inverted taper. Then, the material can be evaporated.

The auxiliary electrode portion 40 penetrates into the aperture 21 of the first electrode layer 20. Thus, the auxiliary electrode portion 40 can be formed with high adhesiveness. Furthermore, a pad electrode 50 is formed as necessary on the first electrode layer 20. Thus, the semiconductor light emitting device 110 is completed.

### Sixth Embodiment

The sixth embodiment is an example of a method for manufacturing the semiconductor light emitting device 120.

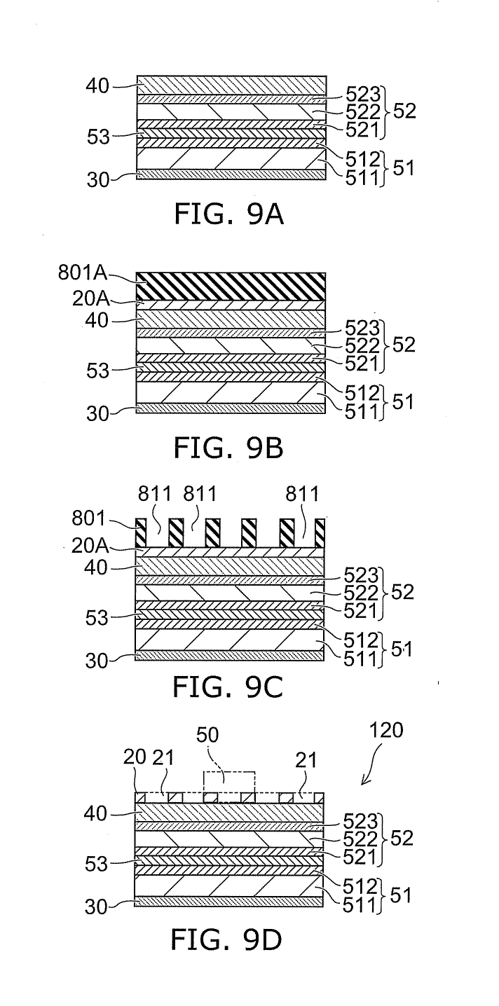

FIGS. 9A to 9D are schematic sectional views describing an example of the method for manufacturing the semiconductor light emitting device 120.

First, as shown in FIG. 9A, a light emitting layer 53 is formed on a first semiconductor layer 51, and a second semiconductor layer 52 is formed on the light emitting layer 53. Furthermore, a second electrode layer 30 is formed on the first semiconductor layer 51.

Next, an auxiliary electrode portion 40 is formed on the contact layer 523 of the second semiconductor layer 52. To form the auxiliary electrode portion 40, resist is applied onto the contact layer 523, and an aperture of the resist is formed at the position for forming the auxiliary electrode portion 40. Through the resist with the aperture formed therein, the material of the auxiliary electrode portion 40 is evaporated. Subsequently, the resist is removed. Thus, the material formed in the aperture of the resist is left on the contact layer 523 and constitutes an auxiliary electrode portion 40.

Next, as shown in FIG. 9B, a metal layer 20A is formed on the auxiliary electrode portion 40. Then, a layer of resist 801A is formed on the metal layer 20A. Next, the resist 801A is patterned to form a resist pattern 801 including resist apertures 811 as shown in FIG. 9C. The resist pattern 801 can be formed by various methods such as a method using self-assembly of block copolymer, a method using a stamper, a method using electron beam writing, and a method using a fine particle mask.

Next, the resist pattern 801 including the resist apertures 811 is used as a mask to perform ion milling to etch the metal layer 20A. Thus, apertures 21 are formed in the metal layer 20A corresponding to the resist apertures 811 (FIG. 9D). The metal layer 20A is turned into a first electrode layer 20 by the formation of the apertures 21. After the etching of the metal layer 20A, the resist pattern 801 is removed. Furthermore, a pad electrode 50 is formed as necessary on the first electrode layer 20. Thus, the semiconductor light emitting device 120 is completed.

### Seventh Embodiment

The seventh embodiment is an example of a method for manufacturing the semiconductor light emitting device 130.

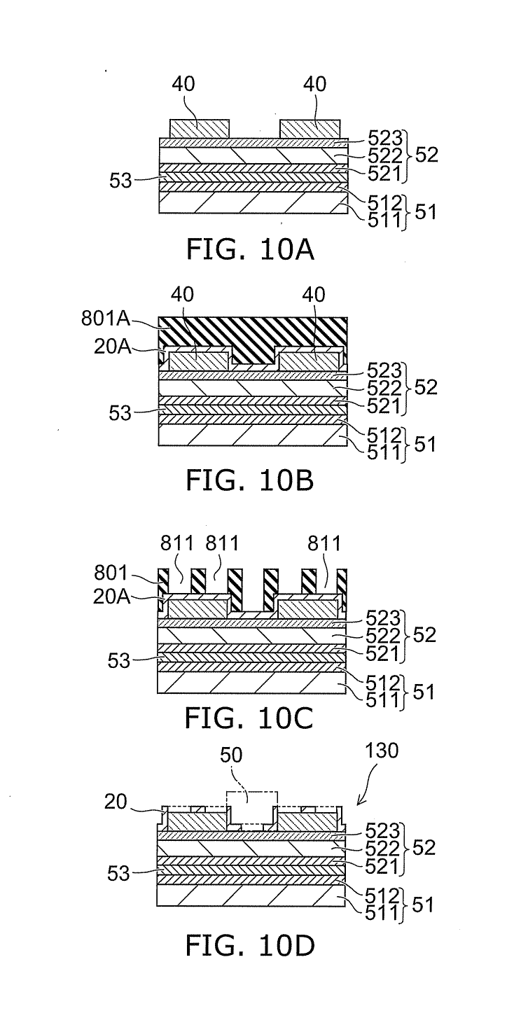

FIGS. 10A to 10D are schematic sectional views describing an example of the method for manufacturing the semiconductor light emitting device 130.

First, as shown in FIG. 10A, a light emitting layer 53 is formed on a first semiconductor layer 51, and a second semiconductor layer 52 is formed on the light emitting layer 53. Furthermore, a second electrode layer 30 is formed on the first semiconductor layer 51.

Next, an auxiliary electrode portion 40 is formed on the contact layer 523 of the second semiconductor layer 52. To form the auxiliary electrode portion 40, resist is applied onto the contact layer 523, and an aperture of the resist is formed at the position for forming the auxiliary electrode portion 40. Through the resist with the aperture formed therein, the material of the auxiliary electrode portion 40 is evaporated. Subsequently, the resist is removed. Thus, the material formed in the aperture of the resist is left on the contact layer 523 and constitutes an auxiliary electrode portion 40. The auxiliary electrode portion 40 is formed in the state of being divided on the contact layer 523.

Next, as shown in FIG. 10B, a metal layer 20A is formed on the auxiliary electrode portion 40. Then, a layer of resist 801A is formed on the metal layer 20A. Next, the resist 801A is patterned to form a resist pattern 801 including resist apertures 811 as shown in FIG. 10C. The resist pattern 801 can be formed by various methods such as a method using self-assembly of block copolymer, a method using a stamper, a method using electron beam writing, and a method using a fine particle mask.

Next, the resist pattern 801 including the resist apertures 811 is used as a mask to perform ion milling to etch the metal layer 20A. Thus, apertures 21 are formed in the metal layer 20A corresponding to the resist apertures 811 (FIG. 10D). The metal layer 20A is turned into a first electrode layer 20 by the formation of the apertures 21. After the etching of the metal layer 20A, the resist pattern 801 is removed. Furthermore, a pad electrode 50 is formed as necessary on the first electrode layer 20. Thus, the semiconductor light emitting device 130 is completed.

### Eighth Embodiment

The eighth embodiment is an example of a method for manufacturing the semiconductor light emitting device 140.

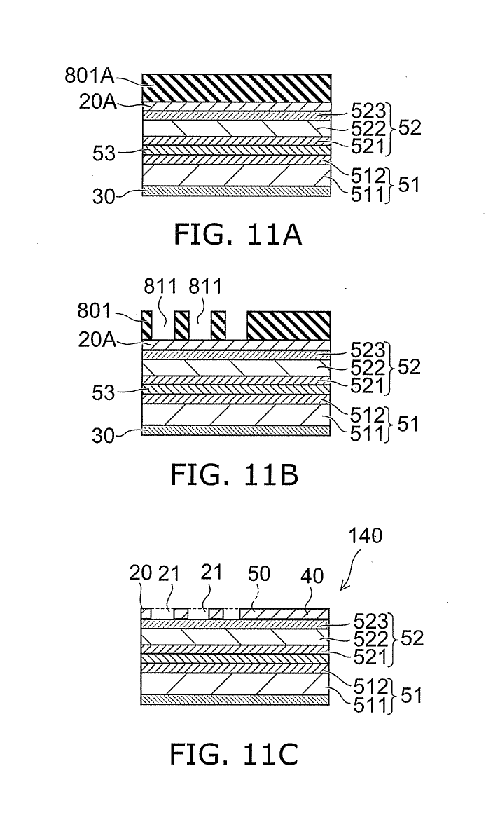

FIGS. 11A to 11C are schematic sectional views describing an example of the method for manufacturing the semiconductor light emitting device 140.

First, as shown in FIG. 11A, a light emitting layer 53 is formed on a first semiconductor layer 51, and a second semiconductor layer 52 is formed on the light emitting layer 53. Furthermore, a second electrode layer 30 is formed on the first semiconductor layer 51.

Next, a metal layer 20A is formed on the contact layer 523 of the second semiconductor layer 52. Then, a layer of resist 801A is formed on the metal layer 20A.

Next, the resist 801A is patterned to form a resist pattern 801 including resist apertures 811 as shown in FIG. 11B. The resist pattern 801 can be formed by various methods such as a method using self-assembly of block copolymer, a method using a stamper, a method using electron beam writing, and a method using a fine particle mask.

This patterning of the resist 801A is performed so that no resist aperture 811 is formed at the position for forming an auxiliary electrode portion 40 and a pad electrode 50 in a later process.

Next, the resist pattern 801 including the resist apertures 811 is used as a mask to perform ion milling to etch the metal layer 20A. Thus, apertures 21 are formed in the metal layer 20A corresponding to the resist apertures 811 (FIG. 11C). The metal layer 20A is turned into a first electrode layer 20 by the formation of the apertures 21. On the other hand, in the portion where the resist apertures 811 are not formed, the metal layer 20A is not etched, but left as an auxiliary electrode portion 40. Furthermore, a pad electrode 50 is formed as necessary. After the etching of the metal layer 20A, the resist pattern 801 is removed. Thus, the semiconductor light emitting device 140 is completed.

In the examples of the method for manufacturing the semiconductor light emitting device described above, using a resist pattern as a mask, the metal layer 20A is etched to form apertures 21. However, the apertures 21 may be formed by other methods. Furthermore, in the examples of the semiconductor light emitting device and the method for manufacturing the same described above, the second electrode layer 30 is provided on the rear surface side of the light emitter 100. However, the second electrode layer 30 may be provided on the front surface side of the light emitter 100.

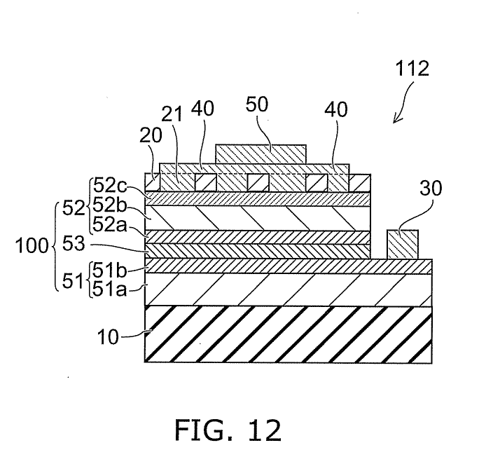

FIG. 12 is a schematic sectional view illustrating an alternative semiconductor light emitting device.

In this semiconductor light emitting device 112, the second electrode layer 30 is provided on the front surface side of the light emitter 100.

In this semiconductor light emitting device 112, the light emitter 100 is formed on a growth substrate 10. More specifically, a first semiconductor layer 51 is formed on the growth substrate 10 such as a sapphire substrate. The first semiconductor layer 51 includes e.g. a GaN buffer layer 51a and an Si-doped n-type GaN layer 51b. Furthermore, as a light emitting layer 53, an InGaN/GaN MQW layer is formed.

On the light emitting layer 53, a second semiconductor layer 52 is formed. The second semiconductor layer 52 includes e.g. an Mg-doped p-type AlGaN layer 52a and an Mg-doped p-type GaN layer 52b. Furthermore, a contact layer 52c is provided on the p-type GaN layer 52b.

On this contact layer 52c of the second semiconductor layer 52, a first electrode layer 20 is formed. An auxiliary electrode portion 40 and, as necessary, a pad electrode 50 are formed on the first electrode layer 20. Furthermore, the first electrode layer 20, the second semiconductor layer 52, and the light emitting layer 53 are partly removed by e.g. etching. A second electrode layer 30 is formed on the exposed portion of the first semiconductor layer 51.

Thus, the auxiliary electrode portion 40 is applicable also to the semiconductor light emitting device 112 in which the second electrode layer 30 is provided on the front surface side of the light emitter 100.

In the semiconductor light emitting device 112 illustrated in FIG. 12, the auxiliary electrode portion 40 is provided above the first electrode layer 20. However, the auxiliary electrode portion 40 may be provided below the first electrode layer 20, or in the same layer as the first electrode layer 20.

As described above, in the semiconductor light emitting device and the method for manufacturing the same according to the embodiments, the light emission intensity at the light emitting surface can be made uniform.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor light emitting device comprising:
a light emitter including a first semiconductor layer of a first conductivity type provided on one side of the light emitter, a second semiconductor layer of a second conductivity type provided on one other side of the light emitter, and a light emitting layer provided between the first semiconductor layer and the second semiconductor layer;
a first electrode layer provided on opposite side of the second semiconductor layer from the first semiconductor layer and including a metal layer and a plurality of apertures penetrating through the metal layer along a first direction directed from the first semiconductor layer toward the second semiconductor layer;
a second electrode layer electrically continuous with the first semiconductor layer;
a pad electrode electrically continuous with the first electrode layer; and
an auxiliary electrode portion being electrically continuous with the first electrode layer and extending in a second direction orthogonal to the first direction.

2. The device according to claim 1, wherein
the first electrode layer has a rectangular outline as viewed in the first direction, and
the auxiliary electrode portion extends toward a corner of the rectangular outline of the first electrode layer.

3. The device according to claim 1, wherein
the first electrode layer has a rectangular outline as viewed in the first direction, and
the auxiliary electrode portion extends along an edge of the rectangular outline of the first electrode layer.

4. The device according to claim 1, wherein width along a direction orthogonal to extending direction of the auxiliary electrode portion is narrowed with distance from the second semiconductor layer along the first direction.

5. The device according to claim 4, wherein cross-sectional shape of the auxiliary electrode portion as viewed in the extending direction includes a tapered shape.

6. The device according to claim 4, wherein cross-sectional shape of the auxiliary electrode portion as viewed in the extending direction includes a semicircular shape.

7. The device according to claim 1, wherein the pad electrode and the auxiliary electrode portion are spaced from each other.

8. The device according to claim 1, wherein thickness along the first direction of the auxiliary electrode portion is gradually decreased along extending direction.

9. The device according to claim 1, wherein the auxiliary electrode portion is provided on opposite side of the first electrode layer from the second semiconductor layer.

10. The device according to claim 1, wherein the auxiliary electrode portion is provided between the first electrode layer and the second semiconductor layer.

11. The device according to claim 1, wherein the auxiliary electrode portion is provided in the first electrode layer.

12. The device according to claim 1, further comprising:
a pad electrode portion being electrically continuous with the first electrode layer and connected with a bonding wire.

13. The device according to claim 1, wherein circle equivalent diameter of the aperture is ½ or less of center wavelength of light generated in the light emitting layer.

14. The device according to claim 1, wherein circle equivalent diameter of the aperture is 10 nanometers or more and 5 micrometers or less.

15. The device according to claim 1, wherein
the auxiliary electrode portion is provided in a plurality, and
the plurality of auxiliary electrode portions are provided radially from the pad electrode.

16. The device according to claim 1, wherein material of the auxiliary electrode portion is buried in the aperture located at a position where the auxiliary electrode portion is provided.

17. A method for manufacturing a semiconductor light emitting device, comprising:
forming a light emitter, the light emitter including a first semiconductor layer of a first conductivity type provided on one side of the light emitter, a second semiconductor layer of a second conductivity type provided on one other side of the light emitter, and a light emitting layer provided between the first semiconductor layer and the second semiconductor layer;
forming a metal layer on the second semiconductor layer;
forming a mask pattern on the metal layer and etching the metal layer through the mask pattern to form an electrode layer including a plurality of apertures penetrating through the metal layer along a first direction directed from the first semiconductor layer toward the second semiconductor layer; and
forming an auxiliary electrode portion, the auxiliary electrode portion being electrically continuous with the electrode layer and extending in a second direction orthogonal to the first direction.

18. A method for manufacturing a semiconductor light emitting device, comprising:
forming a light emitter, the light emitter including a first semiconductor layer of a first conductivity type provided on one side of the light emitter, a second semiconductor layer of a second conductivity type provided on one other side of the light emitter, and a light emitting layer provided between the first semiconductor layer and the second semiconductor layer;
forming an auxiliary electrode portion on the second semiconductor layer, the auxiliary electrode portion extending in a second direction orthogonal to a first direction directed from the first semiconductor layer toward the second semiconductor layer;
forming a metal layer on the second semiconductor layer and the auxiliary electrode portion; and
forming a mask pattern on the metal layer and etching the metal layer through the mask pattern to form an electrode layer including a plurality of apertures penetrating through the metal layer along the first direction.

19. A method for manufacturing a semiconductor light emitting device, comprising:
forming a light emitter, the light emitter including a first semiconductor layer of a first conductivity type provided on one side of the light emitter, a second semiconductor layer of a second conductivity type provided on one other side of the light emitter, and a light emitting layer provided between the first semiconductor layer and the second semiconductor layer;
forming a metal layer on the second semiconductor layer; and
forming a mask pattern on the metal layer and etching the metal layer through the mask pattern to form an electrode layer including a plurality of apertures penetrating through the metal layer along a first direction directed from the first semiconductor layer toward the second semiconductor layer, the electrode layer further including an auxiliary electrode portion extending in a second direction orthogonal to the first direction.
